(19) United States
(12) Patent Application Publication
(10) Pub. No.: US 2020/0105516 A1
(43) Pub. Date: Apr. 2, 2020

(54) METHOD AND DEVICE FOR FORMING A LAYER ON A SEMICONDUCTOR SUBSTRATE, AND SEMICONDUCTOR SUBSTRATE

(71) Applicant: CENTROTHERM INTERNATIONAL AG, Blaubeuren (DE)

(72) Inventors: Jens-Uwe Fuchs, Blaubeuren (DE); Viet Nguyen, Blaubeuren (DE); Thomas Pernau, Blaubeuren (DE); Felix Walk, Blaubeuren (DE)

(21) Appl. No.: 16/604,612

(22) PCT Filed: Apr. 19, 2018
(86) PCT No.: PCT/EP2018/060097

§ 371 Date: Oct. 11, 2019

(30) Foreign Application Priority Data
Apr. 19, 2017 (DE) 10 2017 206 612.1

(51) Int. Cl. H01L 21/02; H01J 37/32; H01L 21/687; C23C 16/455; C23C 16/30; C23C 16/34; C23C 16/458

(52) U.S. Cl. CPC H01L 21/0228; H01J 2237/186; H01L 21/02205; H01L 21/02274; H01L 21/02178; H01L 21/0214; H01L 21/68771; H01J 37/32449; H01L 21/0217; H01L 21/022; C23C 16/45546; C23C 16/45542; C23C 16/45553; C23C 16/308; C23C 16/345; C23C 16/4587; H01J 2237/3321; H01J 2237/3323; H01J 37/32816; H01J 37/32715

(57) ABSTRACT

A method of forming a layer on a plurality of semiconductor substrates is described, wherein the semiconductor substrates are accommodated in a wafer boat such that the semiconductor substrates are arranged in opposed pairs having their surfaces to be coated facing each other, and such that an alternating voltage can be applied between the semiconductor substrates of each pair to generate a plasma between the wafers of a pair, and wherein the wafer boat with the plurality of semiconductor substrates is accommodated in a process chamber. The method comprises the following steps: heating the process chamber to a predetermined temperature and creating a predetermined vacuum in the process chamber; introducing a first precursor gas into the process chamber at the predetermined temperature to create a deposition of a component of the first precursor gas on the surface of the substrate, wherein the deposition is self-limiting and in substance produces a single atomic layer of the deposited component; introducing a second precursor gas into the process chamber at the predetermined temperature to effect reaction with the previously deposited components and to thereby cause the deposition of a component of the second precursor gas on the surface of the substrate, wherein the reaction and thus the deposition is self-limiting and produces one atomic layer of the deposited component. The successive cycles of introducing first and second precursor gases is repeated until a first layer with a predetermined layer thickness or a predetermined number of cycles is reached. Then at least two different precursor gases are introduced into the process chamber and a plasma is generated from the mixture of the precursor gases between the adjacent semiconductor substrates of each pair to deposit a second layer on the first layer, the second layer having substantially the same composition as the first layer.

### RELATED APPLICATIONS

This application corresponds to PCT/EP2018/060097, filed Apr. 19, 2018, which claims the benefit of German Application No 10 2017 206 612.1, filed Apr. 19, 2017, the subject matter of which are incorporated herein by reference in their entirety.

### BACKGROUND OF THE INVENTION

The invention concerns a method and an apparatus for forming a layer on a semiconductor substrate and a semiconductor substrate.

For the production of electronic or optoelectronic semiconductor components, such as solar cells or LEDs, different deposition processes are used to form different layers on a semiconductor substrate.

A well-known deposition process is atomic layer deposition (ALD). In this process, two different precursors are fed alternately and separated by rinsing steps into a process chamber and onto the semiconductor substrates to be coated. This usually results in the following four characteristic steps: a self-limiting reaction of the first precursor with/on the substrate, a purge or evacuation step of the process chamber to remove unreacted gas of the first precursor and, if necessary, further reaction products from the process chamber, a self-limiting reaction/deposition of the second precursor with/on the substrate to form a monolayer of the layer to be formed and again a purge or evacuation step of the process chamber to remove unreacted gas of the second precursor and optionally further reaction products from the process chamber.

This allows individual atomic layers of the layer to be formed to be built up, which exhibit high homogeneity and good interfacial properties. Since individual atomic layers are usually not sufficient to produce the desired layer properties, a plurality of monolayers is applied in the above manner, wherein 100 cycles or more are usual. The formation of the individual monolayers is time-consuming and requires a large material input, as the precursors extracted in the purging or evacuation steps usually cannot be recycled. It is known that individual or all of the self-limiting reactions/deposits can be enhanced thermally or by means of a plasma.

Another known deposition process is plasma enhanced chemical vapor deposition (PECVD), in which, for example, a plasma is generated from a mixture of different precursors in order to simultaneously deposit different components of the individual precursors from the plasma and form a common layer. In this type of PECVD, layers with essentially the same composition as in ALD can be achieved. Since the deposition takes place essentially continuously from the plasma containing both precursors without intermediate purging or evacuation steps, much higher growth rates can be achieved. However, the homogeneity of the layer formed in this way is not as high as that of a comparable layer produced by ALD. In particular, the substrate layer interface is not as good. In order to produce the desired layer properties, larger layer thicknesses are usually required than for comparable layers produced by ALD. PECVD coatings are therefore usually 1.5 to 3 times thicker than comparable ALD coatings. Despite the larger layer thicknesses, PEVCD layers are usually much faster to form and require much less material.

A concrete example of such a layer is an Al₂O₃ passivation layer. Common Al₂O₃ passivation layers produced by the ALD process have thicknesses in the range of 5 nm, while Al₂O₃ passivation layers produced by the PECVD process have thicknesses in the range of at least 8-10 nm. The devices used for the different deposition processes usually differ considerably. In particular, ALD systems having plasma enhancement use individual processes in which a plasma is generated between an electrode which also serves as a gas inlet and a single substrate. For PECVD systems, on the other hand, batch processes are frequently used in which, for example, a plasma is generated between adjacent substrates. Such a PECVD system is for example described in DE 10 2015 004 352.

### SUMMARY OF THE INVENTION

It is an object of the present invention to provide a process and a device for forming a layer on a semiconductor substrate as well as a semiconductor substrate with a special layer structure which at least partially avoid disadvantages of the state of the art.

According to the invention, a method according to claim 1, a device according to claim 14 and a semiconductor substrate with a special layer structure according to claim 15 are provided. Further embodiments of the invention are provided in the dependent claims. In particular, there is provided a method for forming a layer on a plurality of semiconductor substrates, in which the semiconductor substrates are accommodated in a wafer boat in such a way that the semiconductor substrates are arranged in pairs opposite one another and with their surfaces to be coated facing one another, and that an alternating voltage can be applied between the semiconductor substrates of each pair for generating a plasma between the wafers of the pair, wherein the wafer boat with the plurality of semiconductor substrates is accommodated in a process chamber. The method comprises the following steps: heating the process chamber to a predetermined temperature and creating a predetermined vacuum in the process chamber, introducing a first precursor gas into the process chamber at the predetermined temperature to create a deposition of a component of the first precursor gas on the surface of the substrate, wherein the deposition is self-limiting and substantially produces a single atomic layer of the deposited component, introducing a second precursor gas into the process chamber at the predetermined temperature to cause a reaction with the deposited components of the first precursor gas and thereby produce a deposition of a component of the second precursor gas on the surface of the substrate, the reaction and thus the deposition are self-limiting and produce an atomic layer of the deposited component. The cycle of introducing the first and second precursor gases is repeated until a first layer with a predetermined layer thickness or a predetermined number of cycles is reached. Then at least two different precursor gases are introduced into the process chamber and a plasma is generated from the mixture of the precursor gases between the adjacent semiconductor substrates of each pair to deposit a second layer on the first layer, the second layer having substantially the same composition as the first layer.

The method results in a directly sequential combination of an ALD process with a PECVD process within a single process chamber while a plurality of semiconductor substrates is accommodated in the wafer boat and coated simultaneously. This enables high throughput with low gas consumption. In particular, there is also a good ratio between the surface of the semiconductor substrates to be coated and the surfaces of the process chamber (process chamber wall) itself that are not to be coated and other surfaces within the process chamber that are not to be coated (on the wafer boat, on gas supply lines, etc.). The described process sequence results in a semiconductor substrate with a deposited layer structure consisting of a base layer which is produced by the ALD process and a layer with essentially the same composition which is formed by the PECVD process. In this case “essentially the same composition” should contain a deviation within the ratio between the components but no other components. While the ALD process, for example, enables an exact proportionality (stoichiometry) of the components, the CVD process can result in slight deviations. The base layer is characterized by high homogeneity within the layer and good interfacial properties at the substrate-layer interface. The homogeneous base layer also has a positive effect on the further layer formation in the PECVD process, so that it can exhibit an improved homogeneity compared to a layer formed by the PECVD process directly on the semiconductor substrate. In particular, island formation, which frequently occurs in the PPECVD process, can be prevented since the base layer can serve as a nucleus or seed layer for further deposition.

### BRIEF DESCRIPTION OF THE DRAWINGS

The invention is explained in more detail below with reference to the drawings; in the drawings:

FIG. 1 a schematic side view of a wafer boat for holding semiconductor substrates;

FIG. 2 a schematic top view of the wafer boat according to FIG. 1;

FIG. 3 a schematic view of a plasma treatment device accommodating a wafer boat according to FIG. 1 therein;

FIG. 4 a schematic front view of a process chamber of the plasma treatment device according to FIG. 3;

FIG. 5 a schematic top view of a part of a gas supply of the process chamber according to FIG. 4.

### DESCRIPTION

Terms used in the description such as above, below, left and right refer to the representation in the drawings and should not be construed as restrictive. However, they can describe preferred embodiments. The wording, in substance when referring to parallel, vertical or angular values, should include deviations of ±3°, preferably ±2°. In the following, the term wafer is used for wafer-shaped substrates which are preferably semiconductor wafers, especially Si wafers for semiconductor or photovoltaic applications. However, also substrates of other materials may be provided and processed.

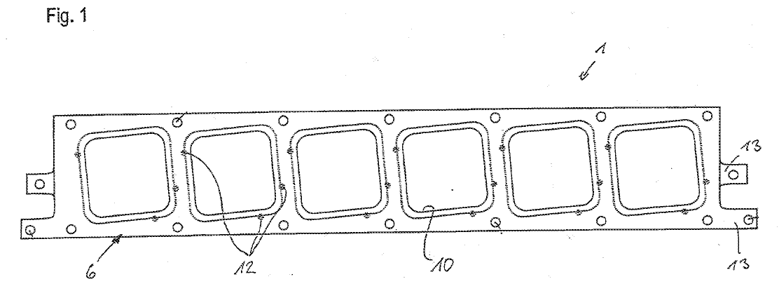

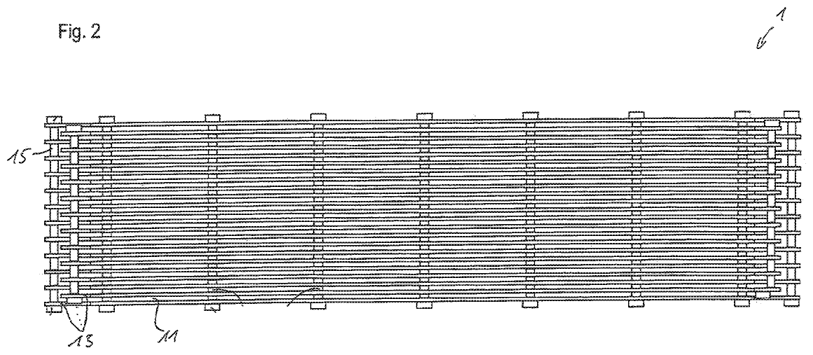

In the following an exemplary design of a wafer boat 1 for use in a process for forming a layer on semiconductor substrates (hereinafter also referred to as wafers) is explained in more detail according to the present disclosure on the basis of FIGS. 1 and 2. The same reference signs are used throughout the figures, provided the same or similar elements are described.

The wafer boat 1 is formed by a plurality of plates 6, contacting units and clamping units. The wafer boat 1 shown is specifically designed for plasma enhanced deposition, but can also be used in thermal deposition.

The plates 6 are each made of an electrically conductive material, and are especially formed as graphite plates, whereby depending on the process a coating or surface treatment of the plate base material can be provided. The plates 6 each have six cut-outs or recesses 10, which are covered by the wafers during the process, as will be explained in more detail below. Although the embodiment as shown has six recesses per plate 6, it should be noted that a larger or smaller number may be provided. The plates 6 each have parallel upper and lower edges, wherein the upper edge may, for example, have a plurality of notches in order to enable position recognition of the plates, as described in DE 10 2010 025 483.

In the embodiment as shown, a total of twenty-three plates 6 are provided, which are arranged in substance parallel to each other via the respective contacting units and clamping units in order to form receiving slots 11 between them. Twenty-three plates 6 thus form twenty-two of the slots 11. In practice, however, 19 or 21 plates are often used and the invention is not limited to a certain number of plates.

The plates 6 each have, at least on their side facing an adjacent plate 6, groups of three receiving elements 12, which are arranged to receive a wafer therebetween. The groups of receiving elements 12 are arranged around each recess 10, as schematically indicated in FIG. 1. The wafers can be received in such a way that the receiving elements contact different side edges of the wafer. In the longitudinal direction of the plate elements (corresponding to the recess 10) a total of six groups of receiving elements are provided for each receiving a semiconductor wafer.

At their ends, the plates 6 each have a protruding contact lug 13, which is used for electrically contacting the plates 6. There are two types of plate 6, which are arranged alternately and are different with regard to the position of the contact lugs 13. The plates of the same type are connected to each other electrically via contact blocks 15. Thus the plates 6, which take up an odd place in the sequence (plates 1, 3, 5 . . . ) are electrically connected together as a group. The plates 6, which occupy an even position in the sequence (plates 2, 4, 6 . . . ) are electrically connected together as a group. This arrangement allows directly adjacent plates 6 to be supplied with different potential, while every second plate can be supplied with the same potential. This allows a plasma to be generated between adjacent wafers received on the plates.

For further details of the structure, please refer to the DE 10 2010 025 483 or DE 10 2015 004 352 already mentioned above, which are included herein by reference with regard to exemplary structures of the wafer boat.

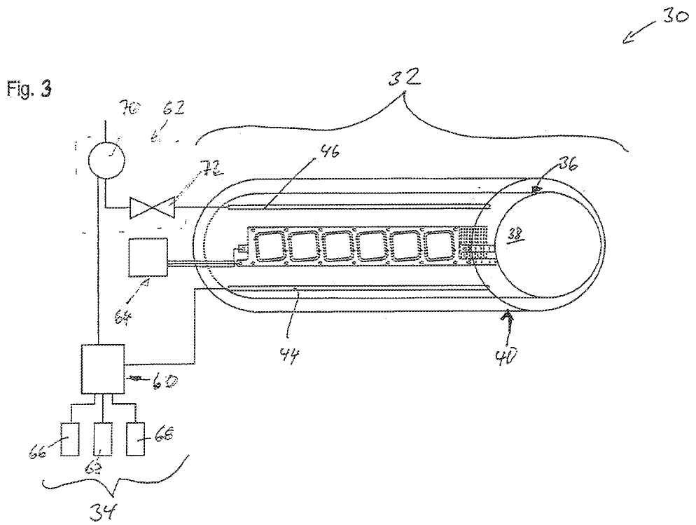

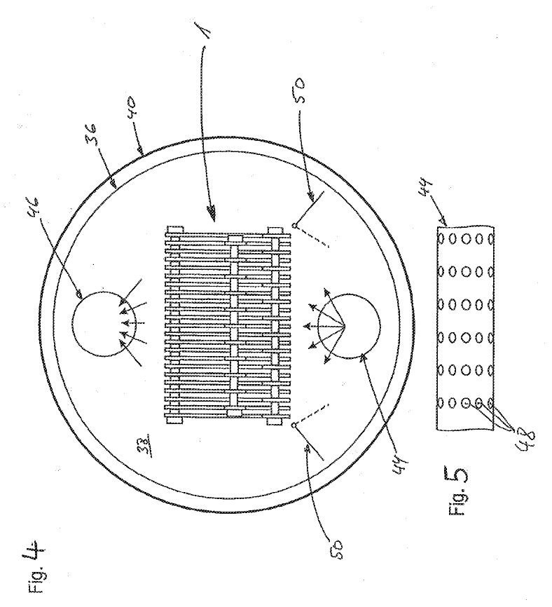

In the following, the basic structure of a plasma treatment device 30, in which a wafer boat 1 of the above type (but also another wafer boat that allows the generation of a plasma between adjacent wafers) can be used, is explained in more detail with reference to FIGS. 3 and 4.

The treatment device 30 has a process chamber part 32 and a control part 34. The process chamber part 32 has a tube element 36 closed on one side, which forms a process chamber 38 inside. The open end of the tube element 36 serves to load the process chamber 38 and it can be closed and hermetically sealed by means of a closing mechanism (not shown), as known in art. The tube element is made of a suitable material that does not introduce any impurities into the process, is electrically insulated and withstands the process conditions with regard to temperature and pressure (vacuum), such as quartz. At its closed end, the tube element 36 has gas-tight feedthroughs for the supply and discharge of gases as well as electricity, which can be formed in a known manner. Corresponding inlet and outlet lines could also be provided at the other end or at a suitable location between the ends.

The tube element 36 is surrounded by a jacket 40, which thermally insulates the tube element 38 from its surroundings. Between the jacket 40 and the tube element 36 there is a heating device (not shown in detail), such as a resistance heater, suitable for heating the tube element 36. However, such a heating device can also be provided, for example, inside the tube element 36 or the tube element 36 itself could be designed as a heating device. At present, however, an external heating device is preferred and in particular one which has different, individually controllable heating circuits.

Inside the tube element 36, support elements (not shown), which form a support plane for supporting a wafer boat 1 (which is only partially shown in FIG. 4), which can for example be of the above type. The wafer boat, however, can also be inserted into the tubular element 36 in such a way that it stands on the wall of the tube element 36. The wafer boat is essentially held above the support plane and is arranged approximately in the middle of the tube element, as can be seen for example in the front view of FIG. 4. By means of respective support elements and or a direct contact with the tube element and in combination with the dimensions of the wafer boat, a receiving space is defined in which a properly inserted wafer boat is located. The wafer boat can be handled as a whole in the loaded state into and out of the process chamber 38 via a suitable handling mechanism which is not shown. When the wafer boat is loaded, a suitable electrical contact is automatically established with each of the groups of plates 6.

Inside the tube element 36, at least one lower gas conduit 44 and one upper gas conduit 46 are additionally provided, which are made of a suitable material such as quartz. The gas conduits 44, 46 extend in the longitudinal direction of the tube element 36 and at least over the length of the wafer boat 1. The gas conduits 44, 46 each have a round cross-section and are arranged in the transverse direction approximately centrally below or above the wafer boat 1. The gas conduits 44, 46 are connected at their respective ends which are closer to the closed end of the tube element 36 to at least one gas supply unit or gas discharge unit, as explained below. The opposite ends of the 44, 46 gas conduits are closed. In principle, however, it is also possible to have a short gas channel in which, for example, gas is injected only at one end of the tube element and is distributed by diffusion and/or pumped via a vacuum port (preferably at the opposite end of the tube element 36).

The lower gas conduit 44 has a plurality of openings 48 through which gas can exit the gas conduit. The openings are all located in an upper half of the gas conduit so that any exiting gas has an upward component. The lower gas conduit 44 thus serves as a gas distributor (shower head) in the process chamber 38. The lower gas conduit 44 should have a large cross-section with a respective number of openings in order to achieve a low pressure loss in the distribution of preferably max. 10 mBar.

The upper gas conduit 46 has a similar structure with openings, therein the openings are formed in the lower half. The gas lines 44, 46 may be in substance identical, but arranged in a different orientation so that the openings face the wafer boat 1. Thus the openings in both the lower gas conduit 44 and the upper gas conduit 46 face the receiving space, i.e. the area where a properly inserted wafer boat is located.

With such gas conduits 44, 46 a good homogeneous gas distribution can be achieved within the process chamber, especially in the receiving slots 11 of the wafer boat. A fast gas change is also possible. For this purpose, for example, gas is preferably supplied to the lower gas conduit, while 46 gas is exhausted via the upper gas conduit. The lower gas conduit 44 ensures a good gas distribution under the wafer boat, and the removal via the upper gas conduit 46 ensures that the gas is transported upwards between the plates 6 of the wafer boat 1.

In order to enhance this effect, i.e. to direct the gas flow especially between the plates 6 of the wafer boat, two optionally movable deflection elements 50 are provided in the process chamber.

The figure shows a lower and an upper gas conduit with a round cross-section. However, it is also possible to provide a different number of gas conduits, in particular two lower gas conduits through which, for example, different gases can be supplied sequentially or simultaneously, so that they only mix in the process chamber. According to an embodiment which is not shown, three lower gas conduits and a single upper gas conduit are provided, which are arranged symmetrically with respect to a vertical centre plane of the process tube. In particular, in this or a similar arrangement with several lower gas conduits for the gas supply, different gases can be introduced into the process chamber sequentially or simultaneously via the different gas conduits. The symmetrical arrangement leads to a good distribution in the process chamber and a good mixing of the gases during simultaneous introduction.

In the following, the control part 34 of the treatment device 30 is explained in more detail. The control part 34 has a gas control unit 60, a vacuum control unit 62, an electrical control unit 64 and temperature control unit (not shown), all of which can be controlled jointly via a higher-level controller, such as a processor. The temperature control unit communicates with the heater unit (not shown), primarily to control the temperature of the tube element 36 or process chamber 38 in an open loop or closed loop manner.

The gas control unit 60 is connected to a variety of different gas sources 66, 67, 68, such as gas cylinders containing different gases. Three gas sources are shown in the embodiment, however, of course any other number can also be provided. For example, a first gas source may contain a first process gas, which contains oxygen and which may comprise at least one of the following: N₂O, a mixture of N₂O and NH₃, H₂O, H₂O₂ and O₃. A second gas source can contain a second process gas, such as TMA or another reactive gas, which is preferably used for layer formation in both an ALD process and a PECVD process. A third gas source may preferably contain a gas suitable for the deposition of a SiON or SiNₓ layer. The gas sources, which of course can also contain other suitable gases, provide the gases at corresponding inlets of the gas control unit 60. In particular, a further gas source for nitrogen or an inert gas, which can for example be used as a purge gas, can also be provided. The gas control unit 60 has at least two outlets, one of which is connected to the lower gas conduit 44 and the other to a pump 70 of the vacuum control unit 62. The gas control unit 60 can connect the gas sources to the outlets in a suitable way and regulate the flow of gas as is known in the art. Thus the gas control unit 60 can introduce different gases into the process chamber sequentially or simultaneously, via the lower gas conduit 44 (or the plurality of lower gas conduits).

The vacuum control unit 62 essentially comprises the pump 70 and a pressure control valve 72. The pump 70 is connected to the upper gas conduit 46 via the pressure control valve 72 and can evacuate the process chamber to a predetermined pressure. The connection between the gas control unit 60 and the pump is used to dilute process gas pumped out of the process chamber with N₂ if necessary.

The electrical control unit 64 has at least one voltage source capable of generating at an output thereof at least a low frequency voltage or a high frequency voltage. The output of the electrical control unit 64 is connected via a suitable line to a contacting unit for the wafer boat in the process chamber 38 to apply the voltage between the groups of plates 6 and to generate a plasma therebetween if desired.

Now, a preferred process for a layer deposition according to this disclosure, which may for example be performed in the above apparatus, will be explained in more detail. In the process, the wafer boat is loaded with semiconductor substrates such that the semiconductor substrates are arranged facing each other in pairs and that their surfaces to be coated face each other. The wafer boat is loaded into the process chamber and contacted in such a way that via the electrical control unit 64 an AC voltage can be applied between the semiconductor substrates of each pair to generate a plasma. With the wafer boat described above, there would be a total of 138 wafer pairs, i.e. 278 wafers would be processed simultaneously. Preferably, the wafer boat should be designed in such a way that at least 200 preferably even more than 300 wafers are simultaneously accommodated and processed.

The process chamber is heated to a predetermined temperature, e.g. in the temperature range of 260-320° C., especially 280-300° (preferably to about 290° C.) and evacuated to a negative pressure, e.g. in the range of 900-1500 mTorr. The chamber can optionally be purged one or more times to create a controlled starting, atmosphere.

Now a first process gas is introduced into the process chamber. This is preferably an oxygen-containing precursor gas to produce a deposition of a component (here preferably oxygen) of the first precursor gas at the surface of the substrate, wherein the deposition is self-limiting and essentially produces a single atomic layer of the deposited component. Any attachment of the component is explicitly considered to be a deposition. The attachment leads to a surface saturation with the component that prefers a certain bonding type, which is changed by the respective attachment. This results in the self-limitation of the deposition in a well-known manner. In particular, O⁻ or OH⁻ precursors can be generated on the substrate surface. The deposition can be accelerated by applying the AC voltage and forming a plasma of the first process gas, or the plasma can promote complete surface saturation or a complete reaction of the first process gas.

Subsequently, the process chamber can be purged to completely remove the first process gas unless it has already fully or sufficiently reacted. A second process gas is then introduced into the process chamber, which is capable of reacting with the deposited component, such as the O⁻ or OH⁻ precursors on the substrate surface, to cause a deposition from the second process gas. In a preferred embodiment, the second process gas is TMA as a precursor gas for an Al deposition. In particular a layer of Al₂O₃ can thus be generated. Also this process is self-limiting since a certain type of bond is preferred for the deposition of Al, which is changed by the deposition itself. Therefore a single atomic layer is deposited.

Subsequently, the process chamber can again be optionally purged to remove the second process gas unless it has already completely reacted. Then the first process gas is introduced into the process chamber again and the above cycle is repeated. The cycle of introducing the first process gas and then second process gas, optionally with the application of a plasma and an intermediate purge, is repeated several times in order to obtain a desired layer thickness. It is preferred to perform less than 100 cycles, in particular less than 50 cycles and in particular less than 10 cycles, in order to obtain a uniform and homogeneous base layer. For the base layer, for example, a layer thickness of at least 1 nm, preferably at least 1.5 nm, can be aimed for. Directly following, without breaking the vacuum, a third process gas can be introduced into the process chamber and a plasma can be generated therefrom to achieve further deposition on the base layer. In particular, the time between the end of the cyclic treatment to produce the base layer and the introduction of the third process gas can be limited to less than 10 seconds, preferably less than 1 second. The third process gas is a mixture of two different precursor gases, and can in particular be a mixture of the first two process gases, such that the layer deposited from this gas has in substance the same composition as the base layer. This deposition is maintained until a desired total thickness of the layer is achieved. In particular, a layer thickness of at least 2.5 nm, in particular of at least 4.5 nm, on the base layer can be aimed for by deposition from the third process gas.

In one embodiment, the different precursor gases can be introduced separately into the process chamber and only be mixed in the chamber. Depending on the application, however, it is also possible to introduce mixed precursor gases. Preferably, the temperature and pressure in the process chamber can be kept in substance constant during and between the above steps.

According to one embodiment, the first process gas comprises at least one of the following: N₂O, a mixture of N₂O and NH₃, H₂O, H₂O₂ and O₃ while as a second process gas for example trimethylaluminium is used to form an Al₂O₃ layer on the substrate surface.

A cover layer and/or optionally a SiON and/or SiNₓ layer can be applied to the layer formed in this way by, for example, subsequently increasing the temperature in the process chamber and introducing a further precursor gas into the process chamber, which causes a respective layer deposition with or without the use of a plasma.

The device described above is suitable for carrying out such a process sequence, but other devices can also be used for the process sequence. The process sequence described results in a semiconductor substrate having a deposited layer structure having a base layer produced by the ALD process and a deposited layer with in substance the same composition produced by the PECVD process. The base layer is characterized by a high homogeneity within the layer and a homogeneous substrate-layer interface. The homogeneous base layer also has a positive effect on the further layer formation in the PECVD process, so that it can exhibit improved homogeneity compared to a layer which is applied by the PECVD process directly onto the semiconductor substrate. In particular, island formation, which frequently occurs in the PPECVD process, can be prevented since the base layer can serve as a nucleus or seed layer for further deposition.

When H₂O is used as the first process gas, this is present during the process in vapor form, wherein liquid H₂O may be fed to an evaporator (near the process chamber), for example by means of a microdosing pump, and can then be introduced into the process chamber in vapor form. It is also possible to introduce liquid H₂O into the process chamber and evaporate it only in the process chamber or in a gas distributor located in the process chamber. An alternative H₂O delivery in vapor form could use a temperature-controlled, vacuum-proof water tank and a low-pressure mass flow controller. As an H₂O process gas quantity 1-7 slm corresponding to 0.8-12 g/min are considered. The delivery of the process gases can be continuous or pulsed. When using a pulsed delivery, over an average time interval the same gas quantity should be achieved over all pulses as with the continuous delivery. The pulsed delivery of at least one process gas can take place in very short pulses (<100 ms), wherein also a combination of pulsed delivery of at least one process gas during the continuous delivery of at least one further process gas is also considered. In the case of a pulsed delivery of at least one process gas, the pulses can be coordinated with a pulsed delivery of electrical power for a plasma generation. This can avoid or at least shorten, purging or waiting cycles for the removal of process gas components which preferably should not be activated by plasma.

1. A method for forming a layer on a plurality of semiconductor substrates, wherein the semiconductor substrates are accommodated in a wafer boat such that the semiconductor substrates are arranged in pairs facing each other and with their surfaces to be coated facing each other and that between the semiconductor substrates of each pair an alternating voltage can be applied for generating a plasma between the wafers of a pair, and wherein the wafer boat with the plurality of semiconductor substrates is accommodated in a process chamber, the method comprising the following steps:
a. heating the process chamber to a predetermined temperature and generating a predetermined vacuum in the process chamber;
b. introducing a first precursor gas into the process chamber at the predetermined temperature to cause a deposition of a component of the first precursor gas on the surface of the substrate, wherein the deposition is self-limiting and substantially produces a single atomic layer of the deposited component;
c. introducing a second precursor gas into the process chamber at the predetermined temperature to effect a reaction with the components deposited in step b. and to thereby cause a deposition of a component of the second precursor gas on the surface of the substrate, wherein the reaction and thus the deposition are self-limiting and produce one atomic layer of the deposited component;
d. repeating the cycle of steps b. and c. until a first layer having a predetermined layer thickness or a predetermined number of cycles is reached; and
e. introducing at least two different precursor gases into the process chamber and generating a plasma from the mixture between the adjacent semiconductor substrates of each pair to deposit a second layer on the first layer, wherein the second layer has, in substance, the same composition as the first layer.

2. The method according to claim 1 wherein the temperature and pressure in the process chamber are maintained substantially constant during and between steps b. to e.

3. The method according to claim 1, wherein the temperature is maintained in a temperature range of 260-320° C., in particular 280-300° and preferably at about 290° C., and the pressure is maintained in a range of 900-1500 mTorr

4. The method according to claim 1, wherein the first precursor gas is an oxygen-containing precursor gas to produce O⁻ or OH⁻ precursors on the substrate surface.

5. The method according to claim 4, wherein the first precursor gas comprises at least one of the following: N₂O, a mixture of N₂O and NH₃, H₂O, H₂O₂ and O₃.

6. The method according to claim 4, wherein in step c. trimethylaluminum is used as precursor gas to form an Al₂O₃ layer on the substrate surface together with the O⁻ or OH⁻ precursors.

7. The method according to claim 1, wherein steps b. and c. are repeated before step d less than 100 times, in particular less than 50 times and in particular less than 10 times.

8. The method according to claim 1, wherein steps b. and c. are repeated until the first layer reaches a layer thickness of at least 1 nm, preferably of at least 1.5 nm.

9. The method according to claim 1, wherein step e. is performed for a period of time to generate a layer thickness of the second layer of at least 2.5 nm, in particular of at least 4.5 nm.

10. The method according to claim 1, wherein the temperature after step e. is increased and a further precursor gas is introduced into the process chamber allowing the deposition of a cover or cap layer, in particular a SiON and/or SiNₓ layer.

11. The method according to claim 1, wherein in step b. a plasma of the first precursor gas is formed between the adjacent semiconductor substrates of each pair.

12. The method according to claim 1, wherein after at least one of steps b. and c. the process chamber is purged to at least partially remove the respective precursor gas from the process chamber.

13. The method according to claim 1, wherein at least 100, preferably at least 150, pairs of semiconductor substrates are accommodated in the process chamber.

14. An apparatus for forming a layer on a plurality of semiconductor substrates, comprising:
a process chamber having at least one supply conduit communicating with at least one gas metering unit and at least one evacuation conduit communicating with an evacuation unit;
a wafer boat for holding a plurality of semiconductor substrates such that the semiconductor substrates are arranged in opposed pairs and have their surfaces to be coated facing each other and such that an alternating voltage can be applied between the semiconductor substrates of each pair to generate a plasma between the wafers of a pair; and
a control unit for controlling the apparatus to perform the method according to claim 1.

15. A semiconductor substrate having a layered structure deposited thereon, wherein a first part of the layered structure has the same composition as a second part of the layered structure and the first part of the layered structure has been deposited on the semiconductor substrate by atomic layer deposition, and the second part of the layered structure has been deposited on the semiconductor substrate by plasma enhanced chemical vapor deposition.

16. A semiconductor substrate having a layered structure deposited thereon, wherein a first part of the layered structure has the same composition as a second part of the layered structure and the first part of the layered structure has been deposited on the semiconductor substrate by atomic layer deposition, and the second part of the layered structure has been deposited on the semiconductor substrate by plasma enhanced chemical vapor deposition, wherein said semiconductor substrate is formed by a process according to claim 1.
